(19) United States
(12) Patent Application Publication
(10) Pub. No.: US 2007/0065732 A1
(43) Pub. Date: Mar. 22, 2007

(54) Photomask providing uniform critical dimension on semiconductor device and method of manufacturing the same

(76) Inventors: Donggun Lee, Hwaseong-Si (KR); Chanuk Jeon, Seongnam-Si (KR); Seongwoon Choi, Suwon-Si (KR); Byunggook Kim, Seoul (KR)

Correspondence Address: MILLS & ONELLO LLP, ELEVEN BEACON STREET, SUITE 605, BOSTON, MA, 02108, US

(21) Appl. No.: 11/446,765

(22) Filed: Jun. 5, 2006

(30) Foreign Application Priority Data
Jun. 14, 2005 (KR) 10-2005-0051118

(51) Int. Cl. G03F 1/00; G03C 5/00; G21K 5/00

(52) U.S. Cl. 430/5; 378/35; 430/322; 430/324

(57) ABSTRACT

An approach to correcting non-uniformity of critical dimension (CD) in a semiconductor wafer includes measuring 0^{th}-order light transmitted through or reflected from a photomask in a plurality of regions of the photomask. The photomask is altered to equalize the 0^{th}-order light from the photomask such that the wafer CD is uniform. The photomask can be altered such as by forming a phase grating on the back side of the photomask or by introducing shadowing elements into the photomask to alter the transmittance of the photomask.

### RELATED APPLICATION

This application relies for priority on Korean Patent Application number 10-2005-0051118, filed on Jun. 14, 2005, in the Korean Intellectual Property Office, the contents of which are incorporated herein in their entirety by reference.

### FIELD OF THE INVENTION

The invention is related to photomasks and methods of manufacturing and using photomasks and, in particular, to a photomask and methods of manufacturing and using photomasks to produce a semiconductor device with uniform critical dimension.

### BACKGROUND OF THE INVENTION

A photomask is a high-precision plate containing microscopic patterns used in fabricating highly integrated electronic circuits on substrates such as semiconductor wafers. A photomask is typically formed from a very flat piece of transparent material such as glass or quartz having a patterned layer of opaque material such as chrome formed on one side.

Photolithography involves projecting an image of the photomask pattern onto the substrate or wafer on which electronic circuits are being fabricated. If the image is repeatedly projected onto the wafer a number of times by repeatedly moving the substrate and mask relative to each other, this is referred to as “stepping.” In this case, the photomask is referred to as a “reticle.”

Ideally, a pattern having a critical dimension (CD) on a photomask produces a pattern on the wafer having the same CD. However, the uniformity of the CD of patterns formed on a wafer using a conventional mask or reticle is affected by various factors, such as the processes by which the photoresist layer being exposed via the photomask is formed, as well as other factors.

Various types of non-uniformity of CD of integrated circuits exist. For example, CD non-uniformity can occur across an entire surface of a single wafer. That is, different regions of the wafer, without regard for the circuits fabricated in the regions, may be different. This results in multiple circuit die being formed having different CDs in the same wafer. Another type on non-uniformity is wafer-to-wafer non-uniformity, in which different wafers produced using the same process steps and the same photomask have different CDs. Another type of CD non-uniformity is intra-die non-uniformity. In this type, different regions within a single circuit chip or die have different CDs.

It is noted that as integration density becomes greater and greater, the size of devices integrated on the wafers within the individual chip die becomes smaller. As a result of this reduction in device size, the intra-die CD non-uniformity becomes a more dominant source of error in fabricating semiconductor devices.

### SUMMARY OF THE INVENTION

The present invention provides a photomask, a method of making a photomask and a method of using a photomask to produce circuits on a substrate such as a semiconductor wafer in which CD non-uniformity, in particular, intra-die CD non-uniformity, is substantially reduced.

According to a first aspect, the invention is directed to a method of making a photomask. According to the method, a substrate having a plurality of regions is provided. The substrate is illuminated with radiation, and an optical property related to interaction of the radiation with the substrate is detected for each of the plurality of regions. An optical parameter related to the optical property in at least one of the regions is altered.

In one embodiment, the optical property is transmission through the substrate. Altering the optical parameter can include forming a structure on the substrate. The structure can include a periodic grating or a non-periodic grating. The non-periodic grating can include a random pattern of grooves in the substrate.

Altering the optical parameter can include changing a property of the substrate. Changing a property of the substrate can include forming a shading element in the substrate. Alternatively, changing a property of the substrate can include deposition of a material on a back surface of the substrate. Alternatively, changing a property of the substrate can include implanting ions into the substrate.

Altering the optical parameter can include forming a structure on the substrate and changing a property of the substrate.

In one embodiment, the optical property is reflectance from the substrate.

The optical property can also be is transmission. The optical parameter can also be reflection.

The optical parameter can be index of refraction, absorption coefficient, or phase.

Altering the optical parameter can include forming a phase altering structure on a surface of the substrate in at least one of the regions. The phase altering structure can be a phase grating. A characteristic of the phase altering structure formed in a region can be related to detected transmission of the region. The characteristic of the phase altering structure can be pattern density of a pattern of grooves formed on the substrate.

Altering the optical parameter can include forming a shadowing element in the substrate in at least one of the regions. Forming the shadowing element can include irradiating the region with a laser to alter transmission in the region.

In one embodiment, the radiation detected for each region is 0^{th}-order diffracted radiation.

According to another aspect, the invention is directed to a method of making a photomask. According to the method, a substrate having a plurality of regions is provided. The substrate is illuminated with radiation. Transmission of the radiation through the substrate is detected for each of the plurality of regions. An optical parameter related to transmission in at least one of the regions is altered. The radiation detected for each region is 0^{th}-order diffracted radiation.

Altering the optical parameter can include forming a structure on the substrate. The structure can include a periodic grating or a non-periodic grating. The non-periodic grating can include a random pattern of grooves in the substrate.

Altering the optical parameter can include changing a property of the substrate. Changing a property of the substrate can include forming a shading element in the substrate. Changing a property of the substrate can include deposition of a material on a back surface of the substrate. Changing a property of the substrate can include implanting ions into the substrate.

Altering the optical parameter can include forming a structure on the substrate and changing a property of the substrate.

In one embodiment, the optical parameter is transmission. In one embodiment, the optical parameter is reflection. In one embodiment, the optical parameter is index of refraction. In one embodiment, the optical parameter is absorption coefficient. In one embodiment, the optical parameter is phase.

Altering the optical parameter can include forming a phase altering structure on a surface of the substrate in at least one of the regions. In one embodiment, the phase altering structure is a phase grating. In one embodiment, a characteristic of the phase altering structure formed in a region is related to detected transmission of the region. The characteristic of the phase altering structure can be pattern density of a pattern of grooves formed on the substrate.

Altering the optical parameter can include forming a shadowing element in the substrate in at least one of the regions. Forming the shadowing element can include irradiating the region with a laser to alter transmission in the region.

According to another aspect, the invention is directed to a method of making a photomask. According to the method, a substrate having a plurality of regions is provided. The substrate is illuminated with radiation. An optical property related to interaction of the radiation with the substrate for each of the plurality of regions is detected. An optical parameter related to the optical property in at least one of the regions is altered, such that a critical dimension (CD) of a wafer being processed using the photomask is substantially uniform.

According to another aspect, the invention is directed to a method of making a photomask. According to the method, a substrate having a plurality of regions is provided. The substrate is illuminated with radiation. An optical property related to interaction of the radiation with the substrate for each of the plurality of regions is detected. Using the detected optical property, an optical parameter related to transmission in at least one of the regions is altered.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a top-level flowchart illustrating one embodiment of the invention.

FIG. 2 is a schematic functional block diagram illustrating the operation of measuring light transmitted through a photomask using a densitometer in accordance with an embodiment of the invention.

FIG. 3 contains two plots of transmission ratio (ΔT/ΔCD) versus incidence angle of light.

FIGS. 4A and 4B contain aerial images related to patterned regions of a photomask that have different CDs. The curves of FIG. 4A plot the CD of four specific patterned regions of a photomask. FIG. 4B is a plot of the intensity of 0^{th}-order light transmitted through the photomask of FIG. 4A for each of the defined regions in FIG. 4A.

FIGS. 5A and 5B are images which illustrate the relationship between the transmittance of 0^{th}-order light through a photomask and the CD of the resulting wafer pattern formed using the photomask, over a variation in light exposure dose.

FIG. 6 is a plot which illustrates the correlation between the dose of light transmitted through the photomask and the dose converted from the CD of the wafer pattern.

FIG. 7 contains a schematic diagram and corresponding transmission intensity curves for a photomask having a pair of patterns formed thereon, before the correction of the invention is implemented.

FIG. 8 contains a schematic diagram and corresponding transmission intensity curves for a photomask having a pair of patterns formed thereon as shown in FIG. 7, after the correction of the invention is implemented.

FIG. 9 contains a schematic diagram and corresponding transmission intensity curves for a photomask having a pair of patterns formed thereon as shown in FIG. 7, after the correction of the invention is implemented.

FIG. 10 is a flowchart illustrating the logical flow of one embodiment of the method of making a photomask of the invention.

FIG. 11 is a flowchart illustrating more detailed logical flow of one embodiment of a method of making a photomask according to the invention.

FIG. 12 is a detailed flowchart illustrating the logical flow of step 305 of FIG. 11.

FIG. 13 is a detailed flowchart illustrating the logical flow of step 3051 of FIG. 12.

FIG. 14 is a flowchart illustrating the logical flow of one embodiment of a method of making a photomask according to the invention.

FIG. 15 contains a schematic block diagram of a densitometry system for performing the densitometry measurements described herein in accordance with the invention in a reflective mode.

FIG. 16 contains a schematic block diagram of one embodiment of the reflective photomask shown in FIG. 15.

FIG. 17 contains a flowchart illustrating the logical flow of a method of making a reflective photomask with wafer CD correction, according to an embodiment of the invention.

FIG. 18 is a detailed flowchart illustrating step 603 of FIG. 17 in detail.

### DETAILED DESCRIPTION OF PREFERRED EMBODIMENTS OF THE INVENTION

In the following description, when a layer is described as being formed on another layer or on a substrate, the layer may be formed on the other layer or on the substrate, or a third layer may be interposed between the layer and the other layer or the substrate.

Typically, CD non-uniformity in a wafer can be caused by various sources of error. These include the exposure tool, the wafer substrate, the wafer production process, the mask or reticle and other sources of error. These sources of error have an effect on the CD uniformity budget run-to-run (R2R), that is, over multiple groups of wafers processed in multiple respective production runs; wafer-to-wafer, that is, over multiple wafers within a single run; intra-wafer, that is, within a single wafer; and intra-die, that is, within a single die on a wafer. The present invention mitigates intra-die CD non-uniformity by correcting sources of error in the mask or reticle.

Typically, spatial distribution error in the photolithography exposure radiation, i.e., light, CD inaccuracy in the mask or reticle and variation in transmittance of the mask contribute to intra-die CD non-uniformity. In most cases, intra-die CD non-uniformity error is due to a complex combination of causes, including spatial distribution of the exposure light from the exposure tool, CD inaccuracy in the mask and/or the transmittance of the mask.

Conventionally, the effect of spatial distribution of light error from the exposure tool was greater than that of the CD inaccuracy of the mask and variation in transmittance of the mask. However, the effect of spatial distribution of light has decreased because the quality of the exposure tool has improved through various compensation methods. On the other hand, the effect of inaccuracy of the CD and transmittance of the mask has increased as semiconductor devices continue to shrink in size. The present invention is directed to reducing the effect of errors in the mask itself.

Conventionally, the CD of a photomask is measured using a scanning electron microscope (SEM) approach or an optical critical dimension (OCD) approach. In the SEM method, the CD of the photomask is measured directly by irradiating an electron beam onto the photomask and then capturing secondary electrons emitted from the surface of the photomask. This SEM method requires measuring a large number of CDs of the patterns on the photomask to raise the measurement validity and reliability because this approach has some inherent drawbacks such as measurement error and local CD error. However, the number of CDs that can be measured is limited by the constraints of production efficiency. This limitation in the number of CDs that can be measured causes difficulty in obtaining CD measurement results with adequate measurement validity and reliability.

The OCD method measures the CD of the photomask by capturing only reflected radiation from the photomask pattern. However, this approach has some inherent inaccuracy because radiation transmitted through the photomask is important in transferring the photomask pattern to the photoresist on the wafer or substrate being processed. Additionally, the OCD approach can only be used to measure CDs of only line and space patterns, not all of the various possible patterns on a photomask.

A conventional method for compensating for the erroneous CD of a photomask or improving the CD uniformity of a wafer is based on the CD of the patterned wafer. That is, errors in CD of the wafer are measured in order to determine corrections to be made to the photomask. Various factors such as the measured CD of the wafer, the CD trend on the wafer according to changes in exposure energy and the resulting CD correction amount are required to apply the conventional method. In the conventional approach, after the wafer measurements are made, the CD of the photomask is compensated by controlling, e.g., dropping, the transmittance of predetermined regions of the photomask. This dropping of the transmittance of the photomask can be accomplished by forming one or more diffraction gratings on the back side of the photomask, i.e., the side of the photomask opposite the opaque photomask pattern, or by forming optical defects within one or more regions of the photomask substrate.

These conventional methods require a large amount of time and expense to accomplish, because the required CD correction is typically calculated after forming multiple patterns on the wafer and performing multiple measurements of resulting CD on the wafer patterns. Correction regions need to be determined and the amount of correction required in each region must be calculated. These measurements of wafer CD and correction determinations and calculations are difficult and time consuming for the reasons described above.

In the present invention, the erroneous CD of a photomask can be compensated to form an aerial image by controlling the intensity of 0^{th}-order light transmitted through the photomask. The present invention provides an approach to compensating for the erroneous CD of the photomask itself which is not related to the conditions of the exposure, such as exposure energy. The approach of the invention does not require measurement of the CD on the wafer being processed.

According to the invention, compensating for erroneous CD of a photomask or improving the resulting CD uniformity on the wafer is based on the intensity distribution of 0^{th}-order light transmitted by the photomask. The intensity distribution of the 0^{th}-order light can be measured according to the invention by a densitometer. If the intensity of the 0^{th}-order light transmitted by the photomask is made to be uniform in accordance with the invention, then the CD of the wafer processed by the photomask will also be uniform.

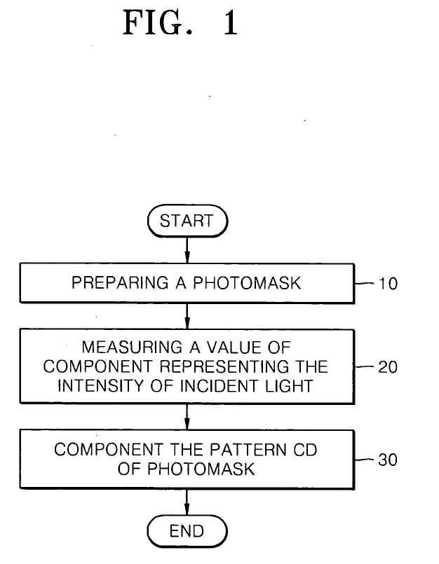

FIG. 1 is a top-level flowchart illustrating one embodiment of the invention. Referring to FIG. 1, in step 10, a photomask including a transparent substrate made of a material such as quartz or glass and a patter of opaque material such as chrome is prepared. In step, 20, a value of a component representing the intensity of incident light is measured. In step 30, compensation is made for the CD of the photomask.

A densitometer is an instrument used according to the invention for measuring and reading the density of a mask pattern directly in a semiconductor device manufacturing process. Pattern densities in regions of the mask are measured and compared to each other using the densitometer.

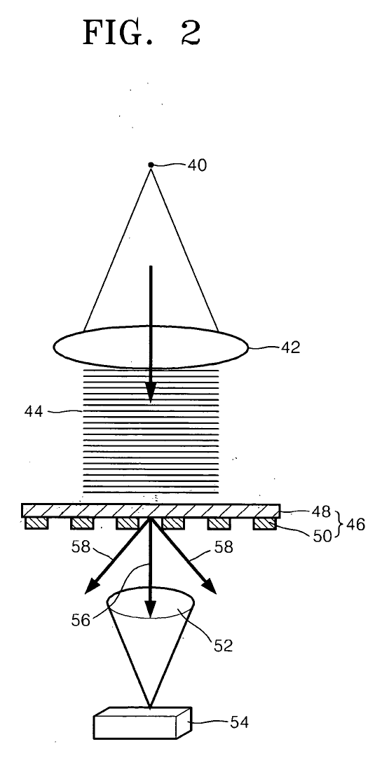

FIG. 2 is a schematic functional block diagram illustrating the operation of measuring light transmitted through a photomask using a densitometer in accordance with an embodiment of the invention. Referring to FIG. 2, a light source 40 emits radiation such as light onto a condenser lens 42. Light 44 from the lens 42 impinges on a surface of the photomask 46, which includes a transparent substrate 48 made of a transparent material such as quartz or glass on which is formed a pattern 50 of opaque material such as chrome. Light 56 and 58 is transmitted through the photomask 46. 0^{th}-order light 56 impinges on an objective lens 52, the size of which is selected such that higher orders 58 of the light from the photomask 46 do not impinge on the lens 52. The 0^{th}-order light collected by the objective lens 52 is directed by the lens 52 onto a photodetector or spectrometer 54 which determines the intensity of the 0^{th}-order light.

The densitometer of FIG. 2 is different from the exposure (scanning) system used to expose a wafer being processed in that the objective lens of the wafer exposure system is large enough to collect higher orders of light and direct them onto the wafer. In contrast, the densitometer used according to the invention detects only the 0^{th}-order light. That is, in general, wafer scanning systems use a larger caliber lens which captures 1^{st} and sometimes 2^{nd} order light in addition to the 0^{th}-order light. In contrast, a densitometer does not require a large caliber lens. A small caliber lens 52 is used to capture only 0^{th}-order light and, according to the invention, the region where light is transmitted is as small as possible so that only 0^{th}-order light, without higher-order light such as 1^{st} and 2^{nd} order light, is transmitted to the measuring system 54.

Also, the angle of incidence of light in the densitometer system is zero degrees. However, the angle of incidence for the scanning system ranges from zero to about ten degrees. Accordingly, the illumination condition of the densitometer system is different than that of the scanning system. The measure of transmission through the photomask is represented by the variable T. Transmission of 0^{th}-order light is denoted by T₀. Generally, the value ΔT/ΔCD, that is, the ratio of the variation in transmission over the variation in CD for a given region of the photomask varies in a range of less than 2% over a range of incidence angle from aero to ten degrees.

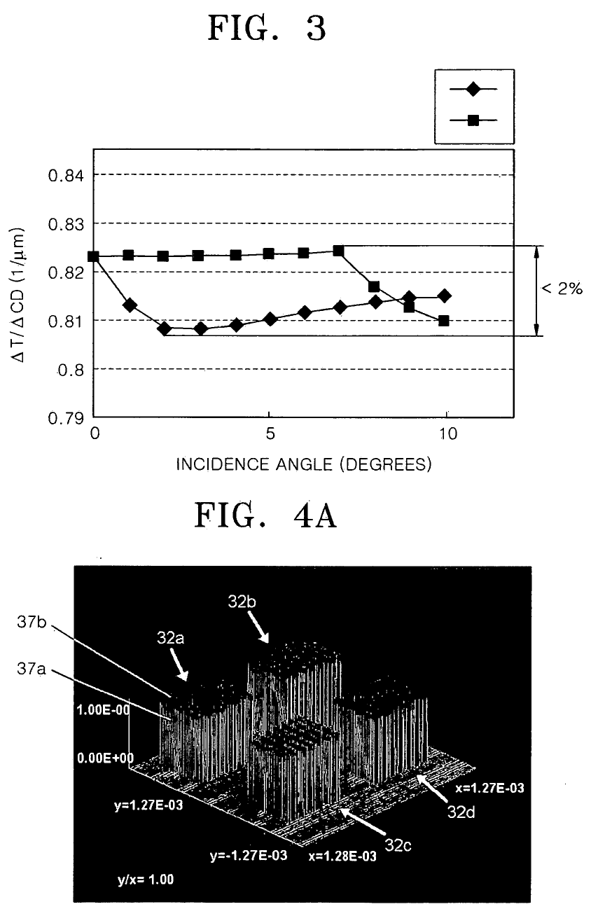

FIG. 3 contains two plots of transmission ratio (ΔT/ΔCD) versus incidence angle of light. The curve marked with upright squares is for incidence angle of light perpendicular to the pattern direction, and the curve marked with diamonds (rotated squares) is for incidence angle of light parallel to the pattern direction. Both curves of FIG. 3 indicate that the total variation in transmission ration with incidence angle is less than 2%. That is, the transmission of 0^{th}-order light in the densitometer system is similar to that of the scanning system, without regard to variation in the illumination condition.

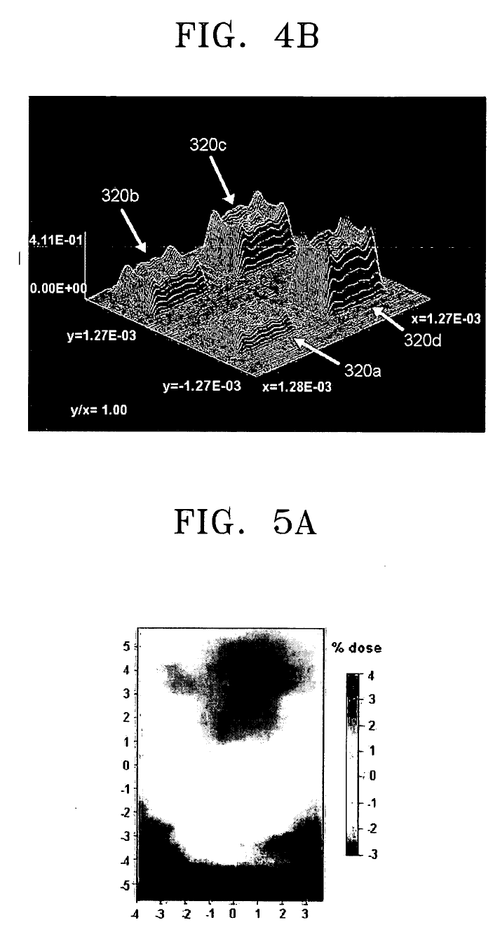

FIGS. 4A and 4B contain aerial images related to patterned regions of a photomask that have different CDs. The curves of FIG. 4A plot the CD of four specific patterned regions of a photomask. By way of illustrative example, region 32a has the smallest CD, region 32b has the next higher CD, region 32c has the next higher CD and region 32d has the highest CD. For example, regions 32a, 32b, 32c and 32d have CDs of 150, 200, 250 and 300 nm, respectively. FIG. 4B is a plot of the intensity of 0^{th}-order light transmitted through the photomask of FIG. 4A for each of the defined regions in FIG. 4A. The transmitted 0^{th}-order light is detected by the densitometer of FIG. 2. As illustrated in FIGS. 4A and 4B, regions with higher CD have higher transmission of 0^{th}-order light. That is, in order of increasing CD, regions 32a, 32b, 32c and 32d have increasing intensity of transmitted 0^{th}-order light 320a, 320b, 320c and 320d, respectively. Thus, the detected intensity of transmitted 0^{th}-order light is related to CD, and, by detecting intensity of transmitted 0^{th}-order light, required corrections to the CDs of individual regions of the photomask can be determined. That is, errors or non-uniformity in CD of a photomask in multiple regions can be compensated and corrected by controlling the intensity of 0^{th}-order light transmitted through the regions.

FIG. 4A describes the light intensity distribution just after the reticle. The reticle includes opaque patterns and transparent patterns. The opaque patterns are made of an opaque material such as Cr or MoSi, and the transparent patterns are typically made of quartz. Reference numerals 37a and 37b represent high intensity regions and low intensity regions just after the reticle, respectively. The regions 37a and 37b are periodically arrayed with high spatial frequency. Accordingly, a high numerical aperture optic system is needed to resolve the regions. However, a 0^{th}-order measurement system has very small numerical aperture, so there is difficulty in resolving the regions 320a and 320b, which have comparably low spatial frequency, even though the regions 37a and 37b can be resolved. That is, regions 37a and 37b cannot be seen individually. Only globally modulated region can be seen in 320b in FIG. 4B. Therefore, due to the low resolving power of the 0^{th}-order measurement system, regions 37a and 37b cannot be seen individually, but the difference of the global CD between 320a and 320b can be resolved by comparing each height of the light intensity.

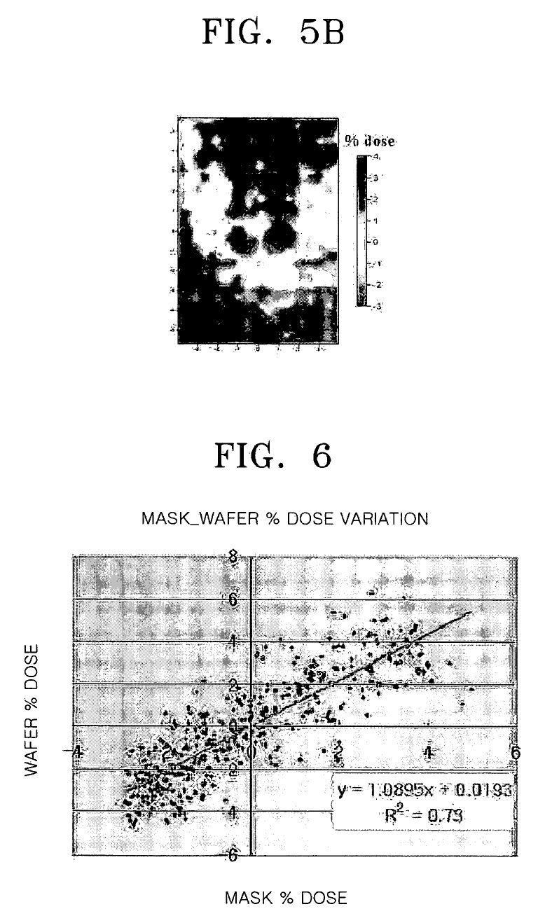

FIGS. 5A and 5B are images which illustrate the relationship between the transmittance of 0^{th}-order light through a photomask and the CD of the resulting wafer pattern formed using the photomask, over a variation in light exposure dose. FIGS. 5A and 5B are based on actual measurements of 0^{th}-order light transmitted through the photomask and detected by a densitometer. The exposure dose variation was realized by using exposure latitude on the photomask. FIG. 5A shows a transmittance uniformity map plot of actual 0^{th}-order light transmission through the photomask with the variation in exposure dose. FIG. 5B is a transmittance uniformity map plot which was generated using actual measurements of wafer CD obtained using a SEM. The wafer CD measurements were translated into transmission values and plotted for comparison to FIG. 5A. The comparison indicates that the actual photomask transmission measurements for the photomask match well with the transmission map generated based on wafer CD. Therefore, in accordance with the invention, FIGS. 5A and 5B illustrate the relationship between 0^{th}-order light transmitted by a photomask and the CD of the wafer produced using the photomask. They illustrate that if the intensity of 0^{th}-order light transmitted by the photomask is uniform, then the resulting wafer CD will be uniform, even if the CD on the photomask is not uniform. This relationship is used according to the invention to alter transmission of 0^{th}-order light in predetermined regions of the photomask to create a uniform CD on the wafer.

FIG. 6 is a plot which illustrates the correlation between the dose of light transmitted through the photomask and the dose converted from the CD of the wafer pattern. The plot of FIG. 6 illustrates that, in general, as the actual measured dose of light transmitted through the photomask increases, so does the dose of light calculated by measuring the corresponding CD on the resulting wafer pattern and converting the measured wafer CD to a photomask transmission in accordance with the invention.

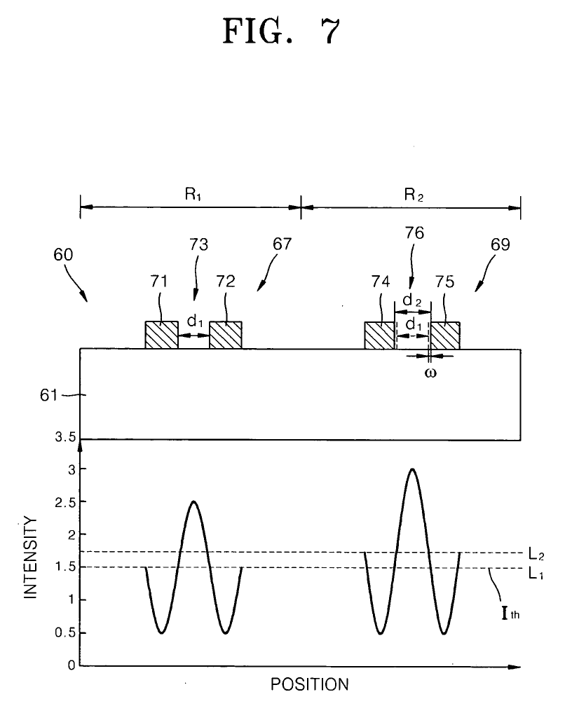

FIG. 7 contains a schematic diagram and corresponding transmission intensity curves for a photomask 60 having a pair of patterns formed thereon, before the correction of the invention is implemented. Referring to FIG. 7, the photomask includes a substrate 61 on which is formed a pair of patterns. A first pattern 67 is formed in a first region R1 of the photomask 60, and a second pattern 69 is formed in a second region R2 of the photomask 60. The first pattern 67 includes two opaque lines 71 and 72, separated by an opening or gap 73, and the second pattern 69 includes two opaque lines 74 and 75 separated by a gap 76. The gap 73 has a width d1, and the second gap 76 has a width d2, which is larger than d1 by twice a distance ω.

The curves below the drawing of the photomask 60 in FIG. 7 represent intensity of light transmitted through the photomask 60. The value of intensity at the inflection points of the curves represents the intensity of 0^{th}-order light. As shown in the intensity curve, in region R1, because of the smaller gap 73, the peak intensity is lower than that of the curve for region R2. Also, the curve for region R1 is associated with an average value L1 that is lower than the average value L2 of the curve for region R2. The CD of the pattern formed on a wafer using the photomask 60 is determined by the width of the intensity curve for each gap at an intensity threshold Ith, which for purposes of this illustration is selected to be equal to L1. Because the intensity curve for region R2 is wider than that for R1 at the intensity threshold Ith, the wafer CD associated with the photomask pattern 69 will be larger than the wafer CD associated with the photomask pattern 67.

It should be noted that this illustration shows wafer CD being affected by variation in transmission intensity due to variation in CD of the photomask. As noted above, other factors affect transmission intensity of the photomask, such as variations in the transmittance of the mask material itself, phase (interference) variations in the photomask, etc. It should be noted that the present invention is applicable to correcting wafer CD non-uniformity caused by variations in photomask transmission caused by any of these factors.

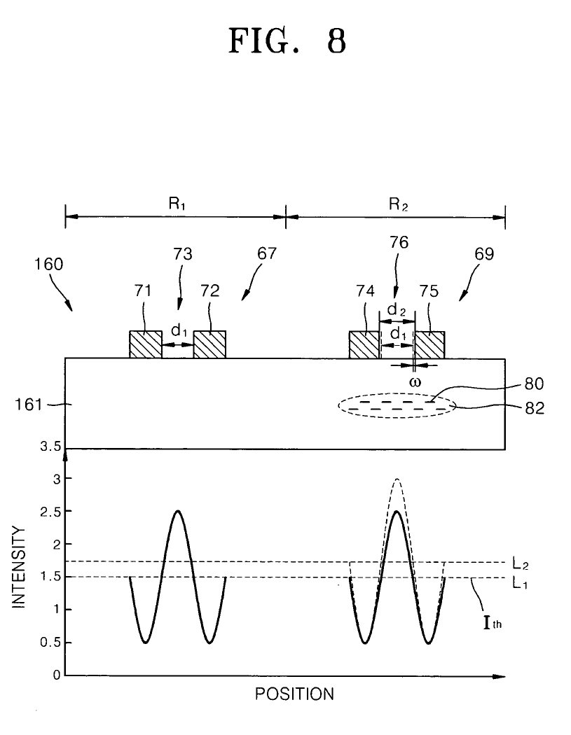

FIG. 8 contains a schematic diagram and corresponding transmission intensity curves for a photomask 160 having a pair of patterns formed thereon as shown in FIG. 7, after the correction of the invention is implemented. In this embodiment, a shadowing region 82 including an array of shadowing elements 80, e.g., optical defects, is generated in the region R2 of the photomask substrate 161 to lower the transmittance of the photomask 160 in region R2. The shadowing elements 80 can be introduced by irradiating the photomask substrate 161 with high-power laser energy or ion implantation. As a result, in the shadowing elements 80, the index of refraction n and the absorption coefficient k of the photomask substrate material are altered in a predetermined fashion to alter the phase of the photomask material and reduce the transmittance of the region R2 of the photomask substrate. The approach to using shadowing elements to alter transmittance of a photomask is described in U.S. Published patent application No. 2004/0214094, the contents of which are incorporated herein in their entirety by reference.

Because of the shadowing region 82, the transmission intensity of the photomask 160 in region R2 is reduced, as illustrated by the corresponding curve of FIG. 8. The average value of the curve is lowered to be approximately equal to that of the transmission intensity curve for region R1. As a result, the width of the intensity curve for region R2 at the intensity threshold value Ith is the same as that of the curve for region R1. As a result, the wafer CDs for the patterns in regions R1 and R2 of the photomask 160 will be equalized.

Other approaches to altering the transmittance of the photomask in the region R2 can also be used in accordance with the invention. For example, a periodic or non-periodic phase grating can be formed on the surface of the photomask substrate opposite the surface on which the photomask pattern is formed.

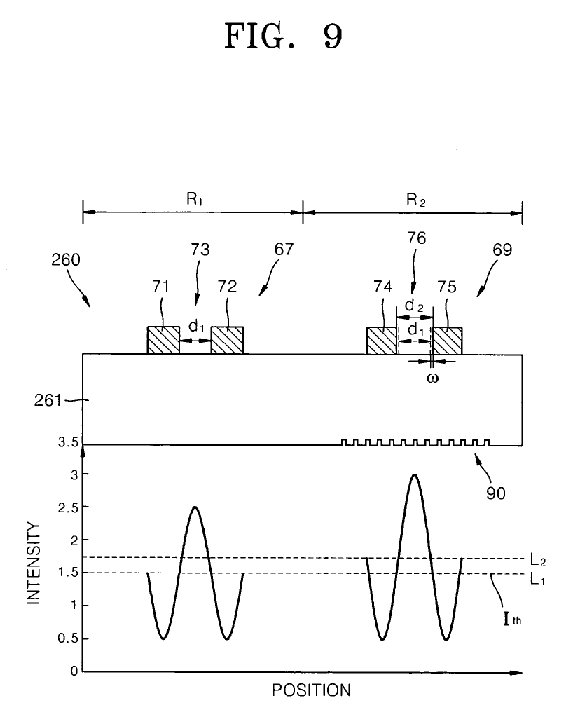

FIG. 9 contains a schematic diagram and corresponding transmission intensity curves for a photomask 260 having a pair of patterns formed thereon as shown in FIG. 7, after the correction of the invention is implemented. In this embodiment, a phase grating such as the non-periodic phase grating 90 is formed on the back side of the substrate 261 of the photomask 260 in the region R2 of the photomask substrate 161 to lower the transmittance of the photomask 160 in region R2. The phase grating 90 can alternatively be a periodic phase grating. The phase grating 90 alters the optical path length through the substrate 261 to introduce a destructive phase shift into the light propagating through the substrate 261. As a result, the intensity of the 0^{th}-order light is substantially reduced and/or higher-order light becomes more dominant. The approach to using phase gratings to alter transmittance of a photomask is described in U.S. Published patent application No. 2004/0067422, the contents of which are incorporated herein in their entirety by reference.

Because of the phase grating 90, the transmission intensity of the photomask 260 in region R2 is reduced, as illustrated by the corresponding curve of FIG. 9. The average value of the curve is lowered to be approximately equal to that of the transmission intensity curve for region R1. As a result, the width of the intensity curve for region R2 at the intensity threshold value Ith is the same as that of the curve for region R1. As a result, the wafer CDs for the patterns in regions R1 and R2 of the photomask 260 will be equalized.

Hence, in accordance with the invention, light transmission through the photomask is determined. This determination is made for all regions of the photomask. The 0^{th}-order light transmission is determined for each region of the photomask, and a map of the photomask based on 0^{th}-order light transmission is generated. Then, a correction map, indicating what correction must be made in each region to equalized the 0^{th}-order light transmission for the photomask. As a result of this equalization, the resulting CDs on the wafers processed by the photomask will be uniform. The correction amount for each region is used to define the mode of the correction to be made to each region. For example, the amount of correction required in a region determines the pitch of a phase grating formed on the back side of the photomask in that region, or the configuration of shadowing elements formed in the region.

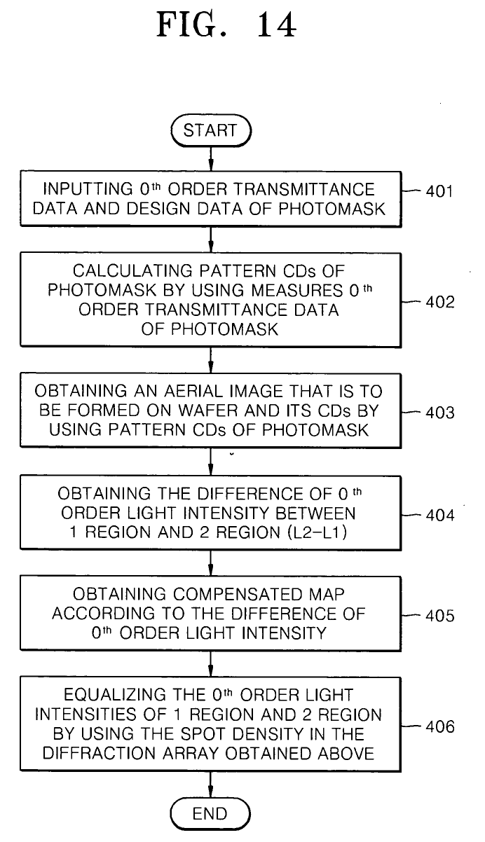

These determinations are made, in one embodiment, by a computer program for determining correction regions and the amount of correction of 0^{th}-order light transmission required for each region. In one embodiment, the computer program executes the logical flow illustrated in FIG. 14, described in detail below. As a result, in one experiment, the global wafer CD error is compensated for up to 92% by executing the program.

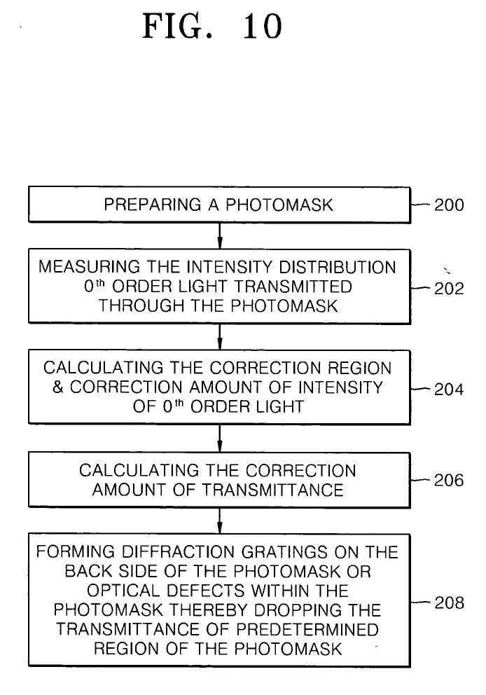

FIG. 10 is a flowchart illustrating the logical flow of one embodiment of the method of making a photomask of the invention. Referring to FIG. 10, in step 200, a photomask is prepared. In step 202, the intensity distribution of 0^{th}-order light transmitted through the photomask is determined. In step 204, the correction regions of the photomask are determined and the correction amount of intensity of 0^{th}-order light for each region is calculated. In step 206, the correction amount for transmittance through the photomask for each region is calculated. In step 208, the photomask correction is made by forming diffraction gratings on the back side of the photomask or optical defects such as shadowing elements within the photomask, thereby reducing the transmittance of 0^{th}-order light in predetermined regions of the photomask.

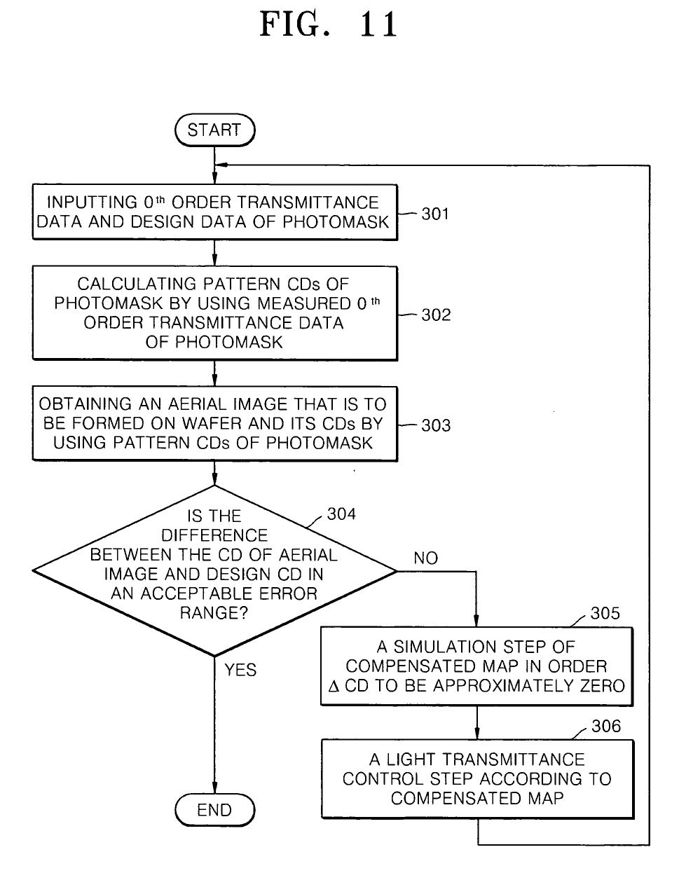

FIG. 11 is a flowchart illustrating more detailed logical flow of one embodiment of a method of making a photomask according to the invention. Referring to FIG. 11, in step 301, 0^{th}-order transmittance data and design data of the photomask are obtained. In step 302, wafer pattern CDs are calculated for the photomask using measured 0^{th}-order transmittance data of the photomask. In step 303, an aerial image that is to be formed on the wafer and its CDs is obtained using pattern CDs of the photomask. In step 304, a determination is made as to whether the difference between the CD of the aerial image and the design CD is in an acceptable range. If so, then the process may terminate. If not, then, in step 305, a compensation map in which ΔCD across the wafer is approximately zero is generated by a simulation. In step 306, light transmittance control and correction are implemented using the compensation map.

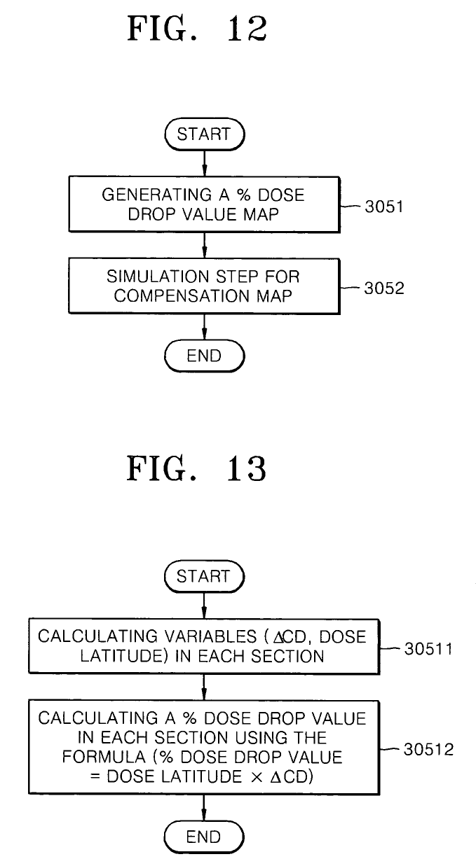

FIG. 12 is a detailed flowchart illustrating the logical flow of step 305 of FIG. 11. Referring to FIG. 12, in step 3051, a percent dose drop value map is generated. This map illustrates the required percentage drop in 0^{th}-order light transmittance required for each region of the photomask. In step 3052, a simulation is performed to generate the compensation map.

FIG. 13 is a detailed flowchart illustrating the logical flow of step 3051 of FIG. 12. Referring to FIG. 13, in step 30511, variables such as ΔCD, dose and latitude are calculated for each region. In step 30512, a percent dose drop value for each region is calculated using the formula: % dose drop=dose latitude X ΔCD.

FIG. 14 is a flowchart illustrating the logical flow of one embodiment of a method of making a photomask according to the invention. Referring to FIG. 14, in step 401, 0^{th}-order transmittance data and design data for the photomask are input. In step 402, pattern CDs of the photomask are calculated using measured 0^{th}-order transmittance data of the photomask. In step 403, An aerial image that is to be formed on the wafer and its CDs are obtained using the pattern CDs of the photomask. In step 404, the difference of 0^{th}-order light intensity between a first region and a second region is obtained. In step 405, the compensation map is generated using the differences calculated for the regions of the photomask calculated in step 404. In step 406, the 0^{th}-order light intensities of the first and second regions are equalized using the spot density in the diffraction array obtained above. The diffraction array is for a two-dimensional spot instead of a one-dimensional line-and-space pattern in the diffraction grating. The efficiency of the intensity drop by using the diffraction array is determined by the density of its two-dimensional spot, i.e., spot density. The diffraction array includes a spot and the spot density determines the efficiency intensity drop of the diffraction array.

The description of preferred embodiments herein has described the invention in terms of a transmissive photomask. However, the invention is also applicable to a reflective photomask. FIG. 15 contains a schematic block diagram of a system 801 for performing the densitometry measurements described herein in accordance with the invention in a reflective mode. A source of extreme ultraviolet (EUV) radiation 802 of approximately 13.5 nm wavelength illuminates the photomask 800 in accordance with the invention. The photomask 800 includes a transparent substrate 805 on which is formed a Si/Mo multilayer structure 804. An absorber pattern 806 is formed over the multilayer structure 804. The EUV radiation 802 penetrates the transparent portions of the photomask 800, i.e., the portions of the substrate on which the absorber pattern 806 is not formed. The portion 808 of the EUV reflected by the absorber pattern 806 is directed to and collected by a photodetector or spectrometer 810. Using the measurements generated by the photodetector or spectrometer 810, the densitometry analysis of the invention is performed.

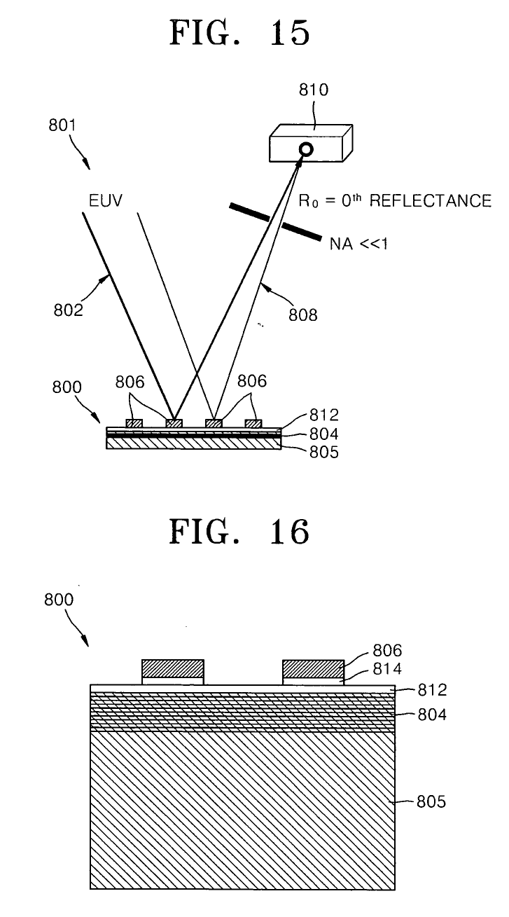

FIG. 16 contains a schematic block diagram of one embodiment of the reflective photomask 800 shown in FIG. 15. As described above, the photomask 800 includes a transparent substrate 805. The substrate 805 can be made of a low thermal expansion material (LTEM) and can be, for example, one-quarter inch thick. The LTEM substrate can be made of Ti-doped fused silica, ULE (made by Corning), Zerodur (made by Schott), etc. The multilayer coating 804 is formed over the substrate 805. The multilayer coating 804 can be a Mo/Si multilayer of approximately 6.7 nm thickness in each layer. A capping layer 812 made of SiO₂ and having a thickness of approximately 30 nm is formed over the multilayer coating 804. The absorber pattern 806 is formed over the substrate 805, the multilayer coating 804 and the capping layer 812. The absorber pattern 806 can be made of Cr or Ta. A buffer layer pattern 814 can be formed between the absorber pattern 806 and the capping layer 812. The reflective photomask 800.

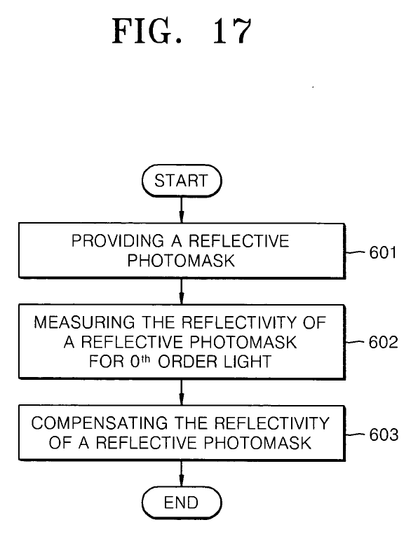

FIG. 17 contains a flowchart illustrating the logical flow of a method of making a reflective photomask with wafer CD correction, according to an embodiment of the invention. Referring to FIG. 15, in step 601, a reflective photomask is provided. In step 602, the reflectivity of 0^{th}-order light for the reflective photomask is measured. In step 603, the reflectivity of the reflective photomask is compensated to make the wafer CD uniform.

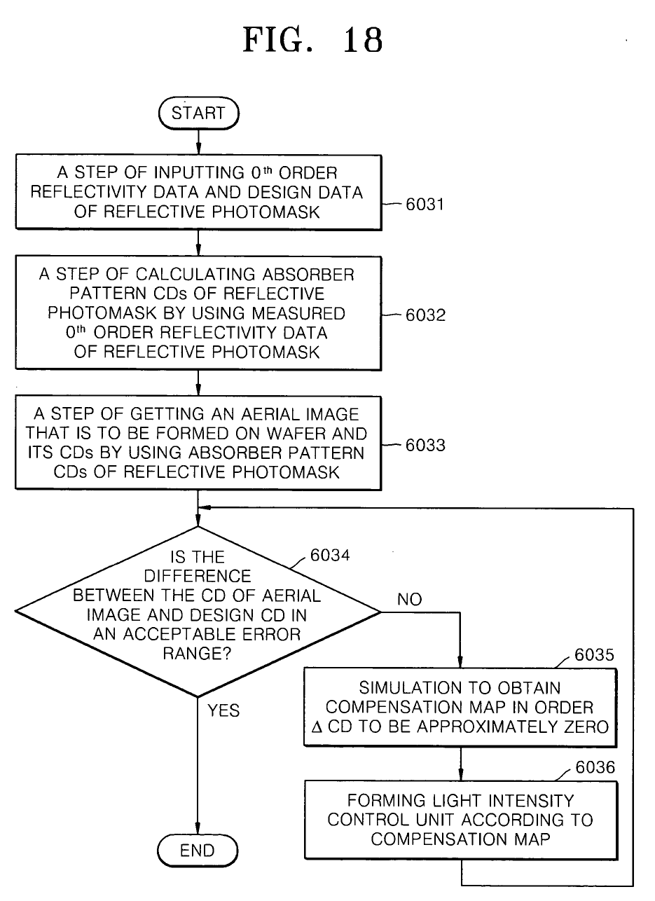

FIG. 18 is a detailed flowchart illustrating step 603 of FIG. 17 in detail. In step 6031, 0^{th}-order reflectivity data and design data for the reflective photomask are input. In step 6032, absorber pattern CDs of the reflective photomask are calculated using measured 0^{th}-order reflectivity data of the reflective photomask._In step 6033, an aerial image that is to be formed on the wafer and its CDs are obtained using the absorber pattern CDs of the reflective photomask. In step 6034, a determination is made as to whether the difference between the CD of the aerial image and the design CD is in an acceptable range. If so, the method can terminate. If not, in step 6035, a simulation is performed to make ΔCD approximately zero. In step 6036, a light intensity control unit is formed according to the compensation map. The light intensity control unit is a system controlling the reflectance of the EUV reticle or photomask by illuminating a high-power laser bean into the multilayer or absorber pattern. The beam can change the material properties of the absorber and, therefore selectively alter its reflectivity. The beam can also be used to change the reflectivity of the multilayer by heating it.

The approach of the invention provides the ability to estimate overall CD distribution of a wafer by measuring properties of the photomask itself, e.g., transmittance and/or reflectance of 0^{th}-order light, instead of having to repeatedly take measurements on the wafers being processed. The invention also enables the reduction in correction time required to correct the photomask by calculating the amount of correction of transmittance using the intensity distribution of 0^{th}-order light of the photomask without processing a wafer and measuring the CD on the wafer. Also, the approach of the invention does not require a large calibre lens and large mirror to capture 1^{st}-order light because, according to the invention, the CD of the wafer can be estimated and corrected by measuring only the intensity of 0^{th}-order light. This reduces the cost of manufacturing semiconductor devices.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of making a photomask, comprising:
providing a substrate, the substrate comprising a plurality of regions;
illuminating the substrate with radiation;
detecting an optical property related to interaction of the radiation with the substrate for each of the plurality of regions; and
altering an optical parameter related to the optical property in at least one of the regions.

2. The method of claim 1; wherein the optical property is transmission through the substrate.

3. The method of claim 2, wherein altering an optical parameter comprises forming a structure on the substrate.

4. The method of claim 3, wherein the structure comprises a periodic grating.

5. The method of claim 3, wherein the structure comprises a non-periodic grating.

6. The method of claim 5, wherein the non-periodic grating comprises a random pattern of grooves in the substrate.

7. The method of claim 2, wherein altering an optical parameter comprises changing a property of the substrate.

8. The method of claim 7, wherein changing a property of the substrate comprises forming a shading element in the substrate.

9. The method of claim 7; wherein changing a property of the substrate comprises deposition of a material on a back surface of the substrate.

10. The method of claim 7, wherein changing a property of the substrate comprises implanting ions into the substrate.

11. The method of claim 2, wherein altering an optical parameter comprises forming a structure on the substrate and changing a property of the substrate.

12. The method of claim 11, wherein the optical property is reflectance from the substrate.

13. The method of claim 1, wherein the optical parameter is transmission.

14. The method of claim 1, wherein the optical parameter is reflection.

15. The method of claim 1, wherein the optical parameter is index of refraction.

16. The method of claim 1, wherein the optical parameter is absorption coefficient.

17. The method of claim 1, wherein the optical parameter is phase.

18. The method of claim 1, wherein altering the optical parameter comprises forming a phase altering structure on a surface of the substrate in at least one of the regions.

19. The method of claim 18, wherein the phase altering structure is a phase grating.

20. The method of claim 18, wherein a characteristic of the phase altering structure formed in a region is related to detected transmission of the region.

21. The method of claim 20, wherein the characteristic of the phase altering structure is pattern density of a pattern of grooves formed on the substrate.

22. The method of claim 1, wherein altering the optical parameter comprises forming a shadowing element in the substrate in at least one of the regions.

23. The method of claim 22, wherein forming a shadowing element comprises irradiating the region with a laser to alter transmission in the region.

24. The method of claim 1, wherein the radiation detected for each region is 0^{th}-order diffracted radiation.

25. A method of making a photomask, comprising:
providing a substrate, the substrate comprising a plurality of regions;
illuminating the substrate with radiation;
detecting transmission of the radiation through the substrate for each of the plurality of regions; and
altering an optical parameter related to transmission in at least one of the regions; wherein
the radiation detected for each region is 0^{th}-order diffracted radiation.

26. The method of claim 25, wherein altering an optical parameter comprises forming a structure on the substrate.

27. The method of claim 26, wherein the structure comprises a periodic grating.

28. The method of claim 26, wherein the structure comprises a non-periodic grating.

29. The method of claim 28, wherein the non-periodic grating comprises a random pattern of grooves in the substrate.

30. The method of claim 25, wherein altering an optical parameter comprises changing a property of the substrate.

31. The method of claim 30, wherein changing a property of the substrate comprises forming a shading element in the substrate.

32. The method of claim 30, wherein changing a property of the substrate comprises deposition of a material on a back surface of the substrate.

33. The method of claim 30, wherein changing a property of the substrate comprises implanting ions into the substrate.

34. The method of claim 25, wherein altering an optical parameter comprises forming a structure on the substrate and changing a property of the substrate.

35. The method of claim 25, wherein the optical parameter is transmission.

36. The method of claim 25, wherein the optical parameter is reflection.

37. The method of claim 25, wherein the optical parameter is index of refraction.

38. The method of claim 25, wherein the optical parameter is absorption coefficient.

39. The method of claim 25, wherein the optical parameter is phase.

40. The method of claim 25, wherein altering the optical parameter comprises forming a phase altering structure on a surface of the substrate in at least one of the regions.

41. The method of claim 40, wherein the phase altering structure is a phase grating.

42. The method of claim 40, wherein a characteristic of the phase altering structure formed in a region is related to detected transmission of the region.

43. The method of claim 42, wherein the characteristic of the phase altering structure is pattern density of a pattern of grooves formed on the substrate.

44. The method of claim 25, wherein altering the optical parameter comprises forming a shadowing element in the substrate in at least one of the regions.

45. The method of claim 44, wherein forming a shadowing element comprises irradiating the region with a laser to alter transmission in the region.

46. A method of making a photomask, comprising:
providing a substrate, the substrate comprising a plurality of regions;
illuminating the substrate with radiation;
detecting an optical property related to interaction of the radiation with the substrate for each of the plurality of regions; and
altering an optical parameter related to the optical property in at least one of the regions, such that a critical dimension (CD) of a wafer being processed using the photomask is substantially uniform.

47. A method of making a photomask, comprising:
providing a substrate, the substrate comprising a plurality of regions;
illuminating the substrate with radiation;
detecting an optical property related to interaction of the radiation with the substrate for each of the plurality of regions; and
using the detected optical property, altering an optical parameter related to transmission in at least one of the regions.
